(19) United States
(12) Patent Application Publication
(10) Pub. No.: US 2025/0211189 A1
(43) Pub. Date: Jun. 26, 2025

(54) PHYSICAL VAPOR DEPOSITION BASED PIEZOELECTRIC RESONATOR STRUCTURE

(71) Applicant: SKYWORKS GLOBAL PTE. LTD., Singapore (SG)

(72) Inventors: Michael David Hill, Emmitsburg, MD (US); Kwang Jae Shin, Yongin-si (KR); Stefan Bader, Fort Collins, CO (US); Alexandre Augusto Shirakawa, Cardiff by the Sea, CA (US); Martha Kennedy Small, Fort Collins, CO (US)

(21) Appl. No.: 18/983,813

(22) Filed: Dec. 17, 2024

Related U.S. Application Data
(60) Provisional application No. 63/612,537, filed on Dec. 20, 2023.

(51) Int. Cl. H03H 9/02; H03H 3/02; H03H 9/17; H03H 9/56

(52) U.S. Cl. CPC H03H 9/02015; H03H 3/02; H03H 9/173; H03H 9/568

(57) ABSTRACT

Disclosed is a bulk acoustic wave resonator including a piezoelectric material layer comprising alternating layers of AlₓSc₁₋ₓN and one of Al_{y}Ga_{1-y}N or Al_{y}In_{1-y}N, 0<x<1, 0<y<1 and methods of forming same.

### CROSS-REFERENCE TO RELATED APPLICATIONS

This application claims priority under 35 U.S.C. § 119 (e) to U.S. Provisional Patent Application Ser. No. 63/612,537, titled “PHYSICAL VAPOR DEPOSITION BASED PIEZOELECTRIC RESONATOR STRUCTURE,” filed Dec. 20, 2023, the entire subject matter of which is incorporated herein by reference.

### TECHNICAL FIELD

Embodiments of this disclosure relate to acoustic wave filters and specifically to piezoelectric films formed by physical vapor deposition having improved properties, to bulk acoustic wave resonators including same, and to acoustic wave resonators including same.

### DESCRIPTION OF RELATED TECHNOLOGY

Acoustic wave filters can filter radio frequency signals. An acoustic wave filter can include a plurality of resonators arranged to filter a radio frequency signal. The resonators can be arranged as a ladder circuit. Example acoustic wave filters include surface acoustic wave (SAW) filters, bulk acoustic wave (BAW) filters, and Lamb wave resonator filters. A film bulk acoustic wave resonator filter is an example of a BAW filter. A solidly mounted resonator (SMR) filter is another example of a BAW filter.

Acoustic wave filters can be implemented in radio frequency electronic systems. For instance, filters in a radio frequency front end of a mobile phone can include acoustic wave filters. Two acoustic wave filters can be arranged as a duplexer.

### SUMMARY

In accordance with one aspect, there is provided a bulk acoustic wave resonator including a piezoelectric material layer comprising alternating layers of AlₓSc₁₋ₓN and one of Al_{y}Ga_{1-y}N or Al_{y}In_{1-y}N, 0<x<1, 0<y<1.

In some embodiments, the bulk acoustic wave resonator further comprises a lower electrode and a seed layer disposed on the lower electrode, the piezoelectric material layer being disposed on the seed layer.

In some embodiments, the seed layer is formed of one of Al_{y}Ga_{1-y}N or Al_{y}In_{1-y}N.

In some embodiments, the layers of one of Al_{y}Ga_{1-y}N or Al_{y}In_{1-y}N are thinner than the layers of AlₓSc₁₋ₓN.

In some embodiments, the layers of one of Al_{y}Ga_{1-y}N or Al_{y}In_{1-y}N are half as thick or less than the layers of AlₓSc₁₋ₓN.

In some embodiments, the layers of one of Al_{y}Ga_{1-y}N or Al_{y}In_{1-y}N are one third as thick or less than the layers of AlₓSc₁₋ₓN.

In some embodiments, x=y.

In some embodiments, x≠y.

In some embodiments, x>y.

In some embodiments, the layers of AlₓSc₁₋ₓN have “a” lattice parameters that are lattice matched to the “a” lattice parameters of the layers of one of Al_{y}Ga_{1-y}N or Al_{y}In_{1-y}N.

In some embodiments, a layer of pure AlN is applied over at least one of the layers of AlₓSc₁₋ₓN.

In some embodiments, the bulk acoustic wave resonator is configured as a film bulk acoustic wave resonator, a Lamb wave resonator, or a surface mounted resonator.

In some embodiments, the bulk acoustic wave resonator is configured as a Lamb wave resonator.

In some embodiments, the bulk acoustic wave resonator is configured as a solidly mounted resonator.

In some embodiments, the bulk acoustic wave resonator is included in an acoustic wave filter.

In some embodiments, the acoustic wave filter comprises a radio frequency filter.

In some embodiments, the acoustic wave filter is included in an electronics module.

An electronic device including In some embodiments, the electronics module is included in an electronic device.

In accordance with another aspect, there is provided a method of forming a bulk acoustic wave resonator. The method comprises forming a lower electrode, depositing a layer of AlₓSc₁₋ₓN above the lower electrode by physical vapor deposition (PVD), 0<x<1, depositing a layer of one of Al_{y}Ga_{1-y}N or Al_{y}In_{1-y}N on the layer of AlₓSc₁₋ₓN, 0<y<1, repeating depositing the layers of AlₓSc₁₋ₓN and one of Al_{y}Ga_{1-y}N or Al_{y}In_{1-y}N until the combined thickness of the deposited layers reaches a desired thickness, and forming an upper electrode on top of the layers of AlₓSc₁₋ₓN and one of Al_{y}Ga_{y-1}N or Al_{y}In_{1-y}N.

In some embodiments, the method further comprises depositing a seed layer of one of Al_{y}Ga_{1-y}N or Al_{y}In_{1-y}N on an upper surface of the lower electrode prior to depositing a first of the layers of AlₓSc₁₋ₓN on an upper surface of the seed layer.

In some embodiments, the method further comprises annealing the lower electrode and seed layer prior to depositing the layer of AlₓSc₁₋ₓN above the lower electrode.

In some embodiments, the layers of one of Al_{y}Ga_{1-y}N or Al_{y}In_{1-y}N are deposited by PVD.

In some embodiments, the layers of one of Al_{y}Ga_{y-1}N or Al_{y}In_{1-y}N are deposited by one or atomic layer deposition of Metal-Organic Chemical Vapor Deposition or a similar method.

In some embodiments, the method further comprises annealing the lower electrode, upper electrode, and the layers of AlₓSc₁₋ₓN and one of Al_{y}Ga_{1-y}N or Al_{y}In_{1-y}N after forming the upper electrode.

### BRIEF DESCRIPTION OF THE DRAWINGS

Embodiments of this disclosure will now be described, by way of non-limiting example, with reference to the accompanying drawings.

FIG. 1 is a cross-sectional view of an example of film bulk acoustic wave resonator;

FIG. 2 is a cross-sectional view of an example of Lamb wave resonator;

FIG. 3 is a cross-sectional view of an example of a surface mounted resonator;

FIG. 4 schematically illustrates a portion of a layered piezoelectric film that may be utilized in bulk acoustic wave resonators;

FIG. 5 illustrates an example of a radio frequency filter;

FIG. 6 illustrates an embodiment of an electronics module;

FIG. 7 illustrates an example of a front-end module which may be used in an electronic device; and

FIG. 8 illustrates an example of an electronic device.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Bulk acoustic wave (BAW) resonators generally includes a film of piezoelectric material sandwiched between a top and a bottom electrode and suspended over a cavity that allows for the film of piezoelectric material to vibrate. A signal applied across the top and bottom electrodes causes an acoustic wave to be generated in and travel through the film of piezoelectric material. A BAW resonator exhibits a frequency response to applied signals with a resonance peak determined by a thickness of the film of piezoelectric material. Ideally, the only acoustic wave that would be generated in a BAW resonator is a main acoustic wave that would travel through the film of piezoelectric material in a direction perpendicular to layers of conducting material forming the top and bottom electrodes. The piezoelectric material of a BAW resonator, however, typically has a non-zero Poisson's ratio. Compression and relaxation of the piezoelectric material associated with passage of the main acoustic wave may thus cause compression and relaxation of the piezoelectric material in a direction perpendicular to the direction of propagation of the main acoustic wave. The compression and relaxation of the piezoelectric material in the direction perpendicular to the direction of propagation of the main acoustic wave may generate transverse acoustic waves that travel perpendicular to the main acoustic wave (parallel to the surfaces of the electrode films) through the piezoelectric material. The transverse acoustic waves may be reflected back into an area in which the main acoustic wave propagates and may induce spurious acoustic waves travelling in the same direction as the main acoustic wave. These spurious acoustic waves may degrade the frequency response of the BAW resonator from what is expected or from what is intended and are generally considered undesirable.

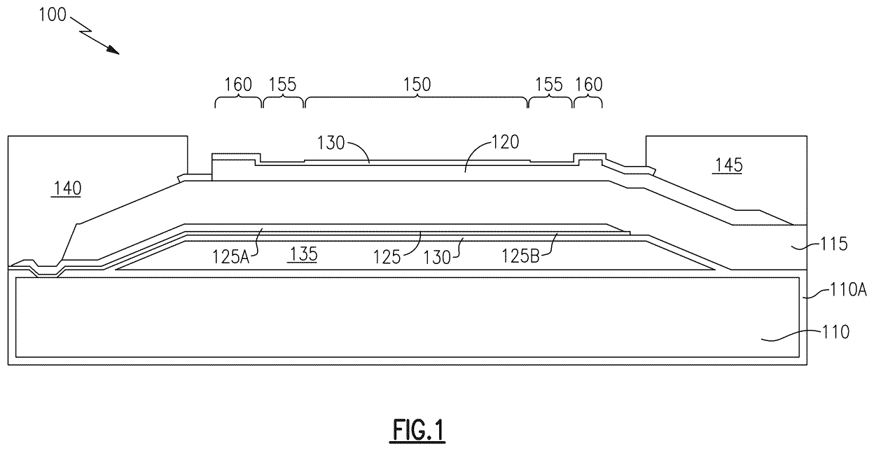

FIG. 1 is cross-sectional view of an example of a BAW resonator, indicated generally at 100. The BAW resonator 100 is disposed on a substrate 110, for example, a silicon substrate that may include a dielectric surface layer 110A of, for example, silicon dioxide. The BAW resonator 100 includes a layer or film of piezoelectric material 115, for example, aluminum nitride (AlN) or scandium-doped aluminum nitride (AlₓSc₁₋ₓN, referred to herein without subscripts as AlScN). A top electrode 120 is disposed on top of a portion of the layer or film of piezoelectric material 115 and a bottom electrode 125 is disposed on the bottom of a portion of the layer or film of piezoelectric material 115. The top electrode 120 may be formed of, for example, ruthenium (Ru). The bottom electrode 125 may include a layer 125A of Ru disposed in contact with the bottom of the portion of the layer or film of piezoelectric material 115 and a layer 125B of titanium (Ti) disposed on a lower side of the layer 125A of Ru opposite a side of the layer 125A of Ru in contact with the bottom of the portion of the layer or film of piezoelectric material 115. Each of the top electrode 120 and the bottom electrode 125 may be covered with a layer of dielectric material 130, for example, silicon dioxide. A cavity 135 is defined beneath the layer of dielectric material 130 covering the bottom electrode 125 and the surface layer 110A of the substrate 110. A bottom electrical contact 140 formed of, for example, copper may make electrical connection with the bottom electrode 125 and a top electrical contact 145 formed of, for example, copper may make electrical connection with the top electrode 120.

The BAW resonator 100 may include a central region 150 including a main active domain in the layer or film of piezoelectric material 115 in which a main acoustic wave is excited during operation. The central region may have a width of, for example, between about 20 μm and about 100 μm. A recessed frame region or regions 155 may bound and define the lateral extent of the central region 150. The recessed frame regions may have a width of, for example, about 1 μm. The recessed frame region(s) 155 may be defined by areas that have a thinner layer of dielectric material 130 on top of the top electrode 120 than in the central region 150. The dielectric material layer 130 in the recessed frame region(s) 155 may be from about 10 nm to about 100 nm thinner than the dielectric material layer 130 in the central region 150. The difference in thickness of the dielectric material in the recessed frame region(s) 155 vs. in the central region 150 may cause the resonant frequency of the device in the recessed frame region(s) 155 to be between about 5 MHz to about 50 MHz higher than the resonant frequency of the device in the central region 150. In some embodiments, the thickness of the dielectric material layer 130 in the central region 150 may be about 200 nm to about 300 nm and the thickness of the dielectric material layer 130 in the recessed frame region(s) 155 may be about 100 nm. The dielectric film 300 in the recessed frame region(s) 155 is typically etched during manufacturing to achieve a desired difference in acoustic velocity between the central region 150 and the recessed frame region(s) 155. Accordingly, the dielectric film 300 initially deposited in both the central region 150 and recessed frame region(s) 155 is deposited with a sufficient thickness that allows for etching of sufficient dielectric film 130 in the recessed frame region(s) 155 to achieve a desired difference in thickness of the dielectric film 130 in the central region 150 and recessed frame region(s) 155 to achieve a desired acoustic velocity difference between these regions.

A raised frame region or regions 160 may be defined on an opposite side of the recessed frame region(s) 155 from the central region 150 and may directly abut the outside edge(s) of the recessed frame region(s) 155. The raised frame regions may have widths of, for example, about 1 μm. The raised frame region(s) 160 may be defined by areas where the top electrode 120 is thicker than in the central region 150 and in the recessed frame region(s) 155. The top electrode 120 may have the same thickness in the central region 150 and in the recessed frame region(s) 155 but a greater thickness in the raised frame region(s) 160. The top electrode 120 may be between about 50 nm and about 500 nm thicker in the raised frame region(s) 160 than in the central region 150 and/or in the recessed frame region(s) 155. In some embodiments the thickness of the top electrode in the central region may be between 50 and 500 nm.

The recessed frame region(s) 155 and the raised frame region(s) 160 may contribute to dissipation or scattering of transverse acoustic waves generated in the BAW resonator 100 during operation and/or may reflect transverse waves propagating outside of the recessed frame region(s) 155 and the raised frame region(s) 160 and prevent these transverse acoustic waves from entering the central region and inducing spurious signals in the main active domain region of the BAW resonator. Without being bound to a particular theory, it is believed that due to the thinner layer of dielectric material 130 on top of the top electrode 120 in the recessed frame region(s) 155, the recessed frame region(s) 155 may exhibit a higher velocity of propagation of acoustic waves than the central region 150. Conversely, due to the increased thickness and mass of the top electrode 120 in the raised frame region(s) 160, the raised frame regions(s) 160 may exhibit a lower velocity of propagation of acoustic waves than the central region 150 and a lower velocity of propagation of acoustic waves than the recessed frame region(s) 155. The discontinuity in acoustic wave velocity between the recessed frame region(s) 155 and the raised frame region(s) 160 creates a barrier that scatters, suppresses, and/or reflects transverse acoustic waves.

Another form of BAW resonator is a Lamb wave acoustic wave resonator. A Lamb wave resonator can combine features of a surface acoustic wave (SAW) resonator and a BAW resonator. A Lamb wave resonator typically includes an interdigital transducer (IDT) electrode similar to a SAW resonator. Accordingly, the frequency of the Lamb wave resonator can be lithographically defined. A Lamb wave resonator can achieve a relatively high quality factor (Q) and a relatively high phase velocity like a BAW resonator (e.g., due to a suspended structure). A Lamb wave resonator that includes an AlN or scandium-doped aluminum nitride piezoelectric material layer can be relatively easy to integrate with other circuits, for example, because AlN process technology can be compatible with complementary metal oxide semiconductor (CMOS) process technology. AlN and AlScN Lamb wave resonators can overcome a relatively low resonance frequency limitation and integration challenge associated with SAW resonators and also overcome multiple frequency capability challenges associated with BAW resonators. Some Lamb wave resonator topologies are based on acoustic reflection from periodic reflective gratings. Some other Lamb wave resonator topologies are based on acoustic reflection from suspended free edges of a piezoelectric material layer.

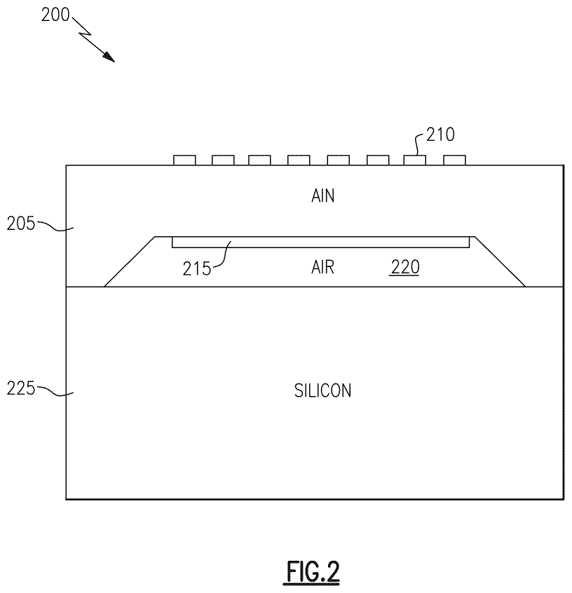

An example of a Lamb wave acoustic wave resonator is indicated generally at 200 in FIG. 2. The Lamb wave resonator 200 includes features of a SAW resonator and a BAW resonator. As illustrated, the Lamb wave resonator 200 includes a piezoelectric material layer 205, an interdigital transducer electrode (IDT) 210 on the piezoelectric material layer 205, and a lower electrode 215 disposed on a lower surface of the piezoelectric material layer 205. The piezoelectric material layer 205 can be a thin film. The piezoelectric material layer 205 can be an aluminum nitride or scandium-doped aluminum nitride layer. In other instances, the piezoelectric material layer 205 can be any suitable piezoelectric material layer. The frequency of the Lamb wave resonator can be based on the geometry of the IDT 210. The electrode 215 can be grounded in certain instances. In some other instances, the electrode 215 can be floating. An air cavity 220 is disposed between the electrode 215 and a semiconductor substrate 225. Any suitable cavity can be implemented in place of the air cavity 220, for example, a vacuum cavity or a cavity filled with a different gas.

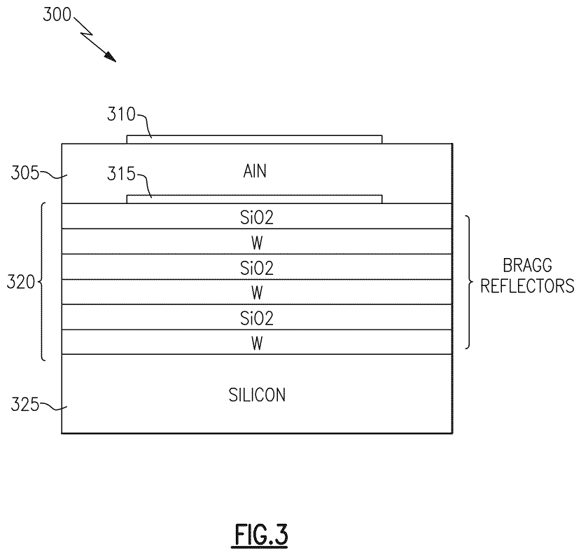

Another form of BAW resonator is a surface mounted resonator (SMR). An example of an SMR is illustrated generally at 300 in FIG. 3. As illustrated, the SMR 300 includes a piezoelectric material layer 305, an upper electrode 310 on the piezoelectric material layer 305, and a lower electrode 315 on a lower surface of the piezoelectric material layer 305. The piezoelectric material layer 305 can be an aluminum nitride or scandium-doped aluminum nitride layer. In other instances, the piezoelectric material layer 305 can be any other suitable piezoelectric material layer. The lower electrode 315 can be grounded in certain instances. In some other instances, the lower electrode 315 can be floating. Bragg reflectors 320 are disposed between the lower electrode 315 and a semiconductor substrate 325. The semiconductor substrate 325 can be a silicon substrate. Any suitable Bragg reflectors can be implemented. For example, the Bragg reflectors can be SiO₂/W.

In some embodiments, it may be preferred to deposit the piezoelectric material layer of a BAW resonator by physical vapor deposition (PVD), for example, by sputtering as opposed to other methods such as metal-oxide chemical vapor deposition (MO-CVD). PVD is a low-cost manufacturing-friendly process which is the current industry standard for thin film deposition. A disadvantage of PVD, however, is that the deposited piezoelectric material film will not typically be in the form of a single crystal, but rather may contain multiple crystal grains. BAW resonator films deposited by PVD, such as those derived from sputtering, typically consist of an <0001> textured Wurtzite crystal structure with long grains extending in the thickness direction of deposition. Depending on the grain size and the degree of orientation, the thermal conductivity in the x-y plane (the plane defining upper and lower surfaces of the film) can be roughly half of that in the z-direction (the thickness direction). For high power applications, enhanced thermal conductivity in the x-y plane would be advantageous. By engineering a BAW piezoelectric material film as multi-layer stack with periodic films with matching “a” lattice parameters (in a textured film, the “a” lattice parameter would be in the x-y plane) to the AlScN films and reducing or eliminating tilt angles from grain boundaries, PVD films can have dramatically improved x-y plane thermal conductivity. PVD is an industry standard technique. Aspects and embodiments disclosed herein may improve the thermal conductivity of PVD piezoelectric film-based resonators for high power applications.

Clean epitaxial boundaries and seed layers with matching lattice parameters reduce the instances of mis-aligned grains in AlScN films which can be Sc atom sinks. Annealing significantly improves the crystallinity of both the Ru electrode and the seed layer deposited on it, so the first steps of building an improved AlScN film as disclosed herein would be to deposit the Ru electrode and deposit a seed layer of AlN or AlInN (for example, a 20 nm thick AlN or AlInN seed layer) with a matching lattice parameter to the Sc-doped film utilized in the resonator. AlInN is specifically used as the seed layer for AlScN. AlN layers may be added as well on top of the electrode or to provide ultra-high thermal conductivity layers within the piezoelectric layer stack. The crystallinity of both the Ru electrode and the seed layer may be improved by annealing both of these layers at a temperature of, for example, about 800° C. Initial steps in forming the improved AlScN piezoelectric film may thus include:
Step 1) Sputter lower electrode (e.g., a Ru electrode)
Step 2) Sputter “a” lattice parameter matching seed layer (for example, a 20 nm thick layer of AlInN)
Step 3) Anneal prior to depositing the rest of the piezoelectric material layer.

Aspects and embodiments disclosed herein include creating a fiber textured AlN layer with a compressive stress and very low mismatch angles.

While MO-CVD based processes can produce essentially grain-boundary free films, sputtered films may exhibit good fiber texture where 30 nm wide AlN (or Sc-doped AlN) grains all have their <0001> planes parallel to one another in the growth direction. There will typically be twist angles in the plane perpendicular to the growth direction, but these are less likely to serve as sinks for Sc ions and less disruptive to thermal pathways than higher angle tilt boundaries.

Sc-doped AlN tends to deviate from the fiber texturing, particularly at distances away from the boundary with the AlN seed layer film. Indeed, even in MO-CVD based films, there is a limiting thickness where solute segregation becomes an issue. Therefore, the next steps in deposition of the improved AlScN film may include interspersing 30-50 nm layers of Sc-doped AlN with 8-10 nm layers of an “a” lattice parameter matched material to create a striated structure. Once this striated piezoelectric material layer is applied and the final electrode etc. are applied, then a second annealing can take place. As the term is used herein an “a” lattice parameter of one material may be considered to be matched to the “a” lattice parameter of another material if the “a” lattice parameters of the two materials differ by less than 5%, less than 3%, or less than 1%.

The advantages of this structure are that it preserves the strong <0001> orientation throughout the film and strongly reduces the possibility of Sc segregation to the grain boundaries and abnormally oriented grain (AOG) formation. This should significantly improve the thermal conductivity of the AlScN film and the quality factor (Q) of a BAW resonator including such a piezoelectric material film. This improved thermal conductivity of the AlScN film should greatly improve the power handling of the BAW resonator. The electromechanical coupling factor may be impacted by the buffer layers, but the resonator can be designed with higher Sc levels to compensate.

Grain boundary misorientation may lead to undesirable dopant segregation at grain boundaries. In some instances the Sc in AlScN films may preferentially diffuse to the grain boundaries in the AlScN film and form a complexion at the grain boundaries where it is concentrated enough to nucleate a layer of Sc rich rock salt phase which then induces an AOG which may grow with further film deposition. The methods and structures disclosed herein result in reduced grain boundary misorientation and reduced dopant concentration at the grain boundaries than might be observed in a pure film of AlScN. This both decreases the potential for the formation of AOGs (improving Quality factor Q), and enhances the x-y plane thermal conductivity of the piezoelectric film.

The grain boundary engineering disclosed herein may thus enhance the thermal conductivity of AlScN sputtered films. The high electromechanical coupling coefficient Sc-doped AlN layers may be diluted with a number of AlGaN and/or AlInN layers. With this structure, higher Sc doping levels may be utilized to compensate for the reduction in electromechanical coupling coefficient due to the AlN films. In any case, the negative impacts of microstructural features on the electromechanical coupling coefficient should be minimized. Another possibility would be to apply a thin (e.g., 2 nm) ALD based “a” lattice matching layer.

In some embodiments, the remaining processing steps for forming the AlScN piezoelectric film and associated electrodes would be as follows:
4) Sputter a 30-50 nm layer of AlScN
5) Sputter an 4-10 nm (or 8-10 nm) layer of a material such as AlInN with an “a” lattice parameter matching the AlScN
6) Repeat steps 4 and 5 until the desired piezoelectric layer stack thickness is achieved
6) Sputter the top electrode (e.g., a Ru electrode)/other layers
7) Anneal

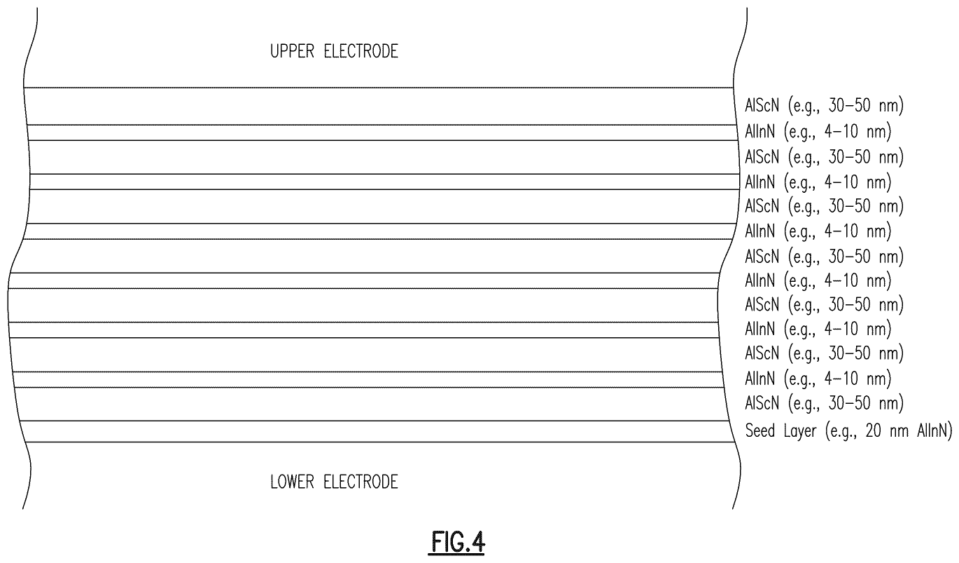

The resulting piezoelectric film may thus appear as shown in FIG. 4. The film shown in FIG. 4 includes seven layers of AlScN and six layers of AlInN, but it is to be understood that the number of layers may be selected to obtain a piezoelectric film having a desired thickness, for example, based on a desired resonance frequency for the resonator. The formulas AlScN and AlInN lack subscripts in FIG. 4 but is it to be understood that these materials would have the formulas AlₓSc₁₋ₓN and Al_{y}In_{1-y}N, 0<x<1, 0<y<1.

Annealing would help eliminate stacking faults and point defects that may be present at the multiple AlN/AlScN interfaces in the piezoelectric material layer.

In some embodiments, the “a” lattice matching material may be AlₓGa₁₋ₓN (also referred to herein without subscripts as AlGaN). The “a” lattice parameters of AlₓGa₁₋ₓN and AlₓSc₁₋ₓN are well matched at low values of 1-x. For example, the “a” lattice parameter of Al_{0.8}Sc_{0.2}N is 0.320 nm, while the “a” lattice parameter of Ga_{0.8}Al_{0.2}N is 0.317 nm. Gallium, however, has a very low melting temperature of 29.76° C. and a liquid phase would exist in a PVD target for AlₓGa₁₋ₓN at temperatures above this, which may render PVD deposition of AlₓGa₁₋ₓN films difficult, if not impractical. AlₓGa₁₋ₓN films, however, may be deposited by other methods such as atomic layer deposition (ALD) or MO-CVD.

In other embodiments, the “a” lattice matching material may be AlₓIn₁₋ₓN (also referred to herein without subscripts as AlInN). The “a” lattice parameters of AlₓIn₁₋ₓN and AlₓSc₁₋ₓN are well matched at values of 1-x up to at least 0.4. Indium has a melting temperature of 156.6° C. so a PVD target of AlₓIn₁₋ₓN would not exhibit a liquid phase until above this temperature, which is more practical for manufacturing. In some embodiments, one may utilize layers of AlₓSc₁₋ₓN and Al_{y}In_{1-y}N where x=y or in other embodiments where x/y to obtain better matching between lattice parameters of the AlScN and AInlN.

Piezoelectric films as disclosed herein having alternating layers of AlScN and an “a” lattice matching material (e.g., AlGaN or AlInN) may be utilized in multiple forms of BAW resonators, for example, any of Lamb wave resonators or SMRs.

It should be appreciated that the BAW resonators and piezoelectric films illustrated in the figures are illustrated in a highly simplified form. The relative dimensions of the different features are not shown to scale. Further, typical BAW resonators may include additional features or layers not illustrated.

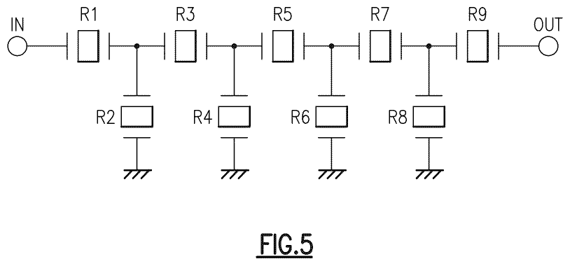

In some embodiments, multiple BAW resonators as disclosed herein may be combined into a filter, for example, an RF ladder filter schematically illustrated in FIG. 5 and including a plurality of series resonators R1, R3, R5, R7, and R9, and a plurality of parallel (or shunt) resonators R2, R4, R6, and R8. As shown, the plurality of series resonators R1, R3, R5, R7, and R9 are connected in series between the input and the output of the RF ladder filter, and the plurality of parallel resonators R2, R4, R6, and R8 are respectively connected between series resonators and ground in a shunt configuration. Other filter structures and other circuit structures known in the art that may include BAW devices or resonators, for example, duplexers, baluns, etc., may also be formed including examples of BAW resonators as disclosed herein.

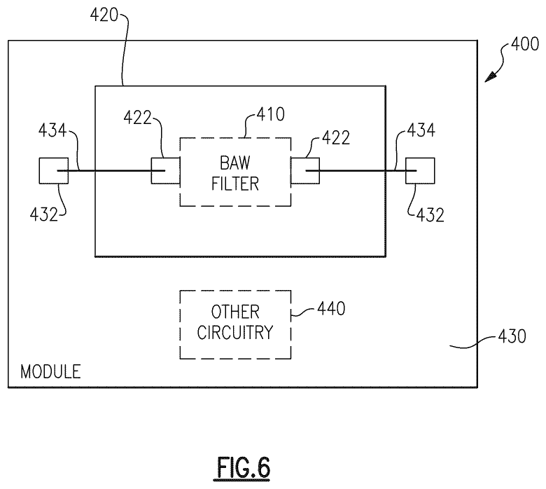

The acoustic wave devices discussed herein can be implemented in a variety of packaged modules. Some example packaged modules will now be discussed in which any suitable principles and advantages of the packaged acoustic wave devices discussed herein can be implemented. FIGS. 6, 7, and 8 are schematic block diagrams of illustrative packaged modules and devices according to certain embodiments.

As discussed above, embodiments of the disclosed BAW resonators can be configured as or used in filters, for example. In turn, a BAW filter using one or more BAW elements may be incorporated into and packaged as a module that may ultimately be used in an electronic device, such as a wireless communications device, for example. FIG. 6 is a block diagram illustrating one example of a module 400 including a BAW filter 410. The BAW filter 410 may be implemented on one or more die(s) 420 including one or more connection pads 422. For example, the BAW filter 410 may include a connection pad 422 that corresponds to an input contact for the BAW filter and another connection pad 422 that corresponds to an output contact for the BAW filter. The packaged module 400 includes a packaging substrate 430 that is configured to receive a plurality of components, including the die 420. A plurality of connection pads 432 can be disposed on the packaging substrate 430, and the various connection pads 422 of the BAW filter die 420 can be connected to the connection pads 432 on the packaging substrate 430 via electrical connectors 434, which can be solder bumps or wirebonds, for example, to allow for passing of various signals to and from the BAW filter 410. The module 400 may optionally further include other circuitry die 440, such as, for example, one or more additional filter(s), amplifiers, pre-filters, modulators, demodulators, down converters, and the like, as would be known to one of skill in the art of semiconductor fabrication in view of the disclosure herein. In some embodiments, the module 400 can also include one or more packaging structures to, for example, provide protection and facilitate easier handling of the module 400. Such a packaging structure can include an overmold formed over the packaging substrate 430 and dimensioned to substantially encapsulate the various circuits and components thereon.

Various examples and embodiments of the BAW filter 410 can be used in a wide variety of electronic devices. For example, the BAW filter 410 can be used in an antenna duplexer, which itself can be incorporated into a variety of electronic devices, such as RF front-end modules and communication devices.

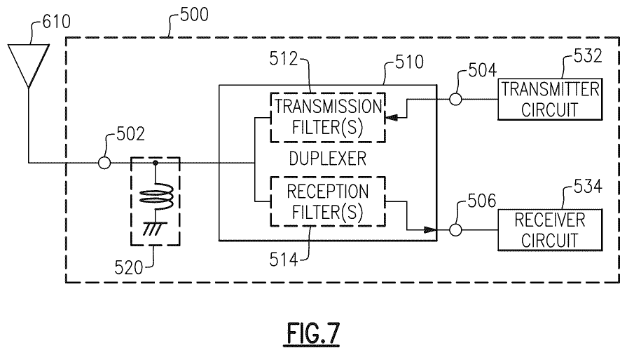

Referring to FIG. 7, there is illustrated a block diagram of one example of a front-end module 500, which may be used in an electronic device such as a wireless communications device (e.g., a mobile phone) for example. The front-end module 500 includes an antenna duplexer 510 having a common node 502, an input node 504, and an output node 506. An antenna 610 is connected to the common node 502.

The antenna duplexer 510 may include one or more transmission filters 512 connected between the input node 504 and the common node 502, and one or more reception filters 514 connected between the common node 502 and the output node 506. The passband(s) of the transmission filter(s) are different from the passband(s) of the reception filter(s). Examples of the BAW filter 410 can be used to form the transmission filter(s) 512 and/or the reception filter(s) 514. An inductor or other matching component 520 may be connected at the common node 502.

The front-end module 500 further includes a transmitter circuit 532 connected to the input node 504 of the duplexer 510 and a receiver circuit 534 connected to the output node 506 of the duplexer 510. The transmitter circuit 532 can generate signals for transmission via the antenna 610, and the receiver circuit 534 can receive and process signals received via the antenna 610. In some embodiments, the receiver and transmitter circuits are implemented as separate components, as shown in FIG. 7, however in other embodiments these components may be integrated into a common transceiver circuit or module. As will be appreciated by those skilled in the art, the front-end module 500 may include other components that are not illustrated in FIG. 7 including, but not limited to, switches, electromagnetic couplers, amplifiers, processors, and the like.

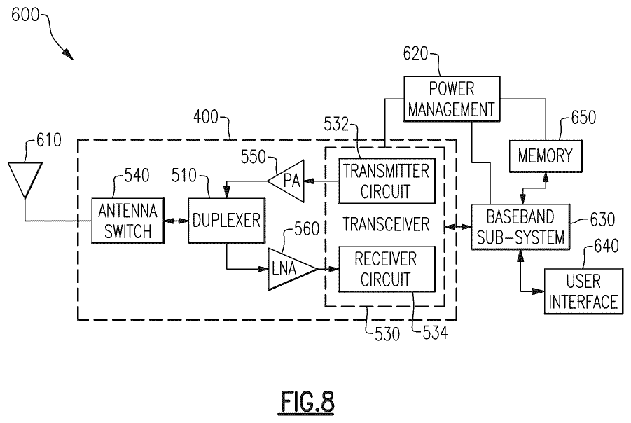

FIG. 8 is a block diagram of one example of a wireless device 600 including the antenna duplexer 510 shown in FIG. 7. The wireless device 600 can be a cellular phone, smart phone, tablet, modem, communication network or any other portable or non-portable device configured for voice or data communication. The wireless device 600 can receive and transmit signals from the antenna 610. The wireless device includes an embodiment of a front-end module 500 similar to that discussed above with reference to FIG. 7. The front-end module 500 includes the duplexer 510, as discussed above. In the example shown in FIG. 8 the front-end module 500 further includes an antenna switch 540, which can be configured to switch between different frequency bands or modes, such as transmit and receive modes, for example. In the example illustrated in FIG. 8, the antenna switch 540 is positioned between the duplexer 510 and the antenna 610; however, in other examples the duplexer 510 can be positioned between the antenna switch 540 and the antenna 610. In other examples the antenna switch 540 and the duplexer 510 can be integrated into a single component.

The front-end module 500 includes a transceiver 530 that is configured to generate signals for transmission or to process received signals. The transceiver 530 can include the transmitter circuit 532, which can be connected to the input node 504 of the duplexer 510, and the receiver circuit 534, which can be connected to the output node 506 of the duplexer 510, as shown in the example of FIG. 7.

Signals generated for transmission by the transmitter circuit 532 are received by a power amplifier (PA) module 550, which amplifies the generated signals from the transceiver 530. The power amplifier module 550 can include one or more power amplifiers. The power amplifier module 550 can be used to amplify a wide variety of RF or other frequency-band transmission signals. For example, the power amplifier module 550 can receive an enable signal that can be used to pulse the output of the power amplifier to aid in transmitting a wireless local area network (WLAN) signal or any other suitable pulsed signal. The power amplifier module 550 can be configured to amplify any of a variety of types of signal, including, for example, a Global System for Mobile (GSM) signal, a code division multiple access (CDMA) signal, a W-CDMA signal, a Long-Term Evolution (LTE) signal, or an EDGE signal. In certain embodiments, the power amplifier module 550 and associated components including switches and the like can be fabricated on gallium arsenide (GaAs) substrates using, for example, high-electron mobility transistors (pHEMT) or insulated-gate bipolar transistors (BiFET), or on a Silicon substrate using complementary metal-oxide semiconductor (CMOS) field effect transistors.

Still referring to FIG. 8, the front-end module 500 may further include a low noise amplifier module 560, which amplifies received signals from the antenna 610 and provides the amplified signals to the receiver circuit 534 of the transceiver 530.

The wireless device 600 of FIG. 8 further includes a power management sub-system 620 that is connected to the transceiver 530 and manages the power for the operation of the wireless device 600. The power management system 620 can also control the operation of a baseband sub-system 630 and various other components of the wireless device 600. The power management system 620 can include, or can be connected to, a battery (not shown) that supplies power for the various components of the wireless device 600. The power management system 620 can further include one or more processors or controllers that can control the transmission of signals, for example. In one embodiment, the baseband sub-system 630 is connected to a user interface 640 to facilitate various input and output of voice and/or data provided to and received from the user. The baseband sub-system 630 can also be connected to memory 650 that is configured to store data and/or instructions to facilitate the operation of the wireless device, and/or to provide storage of information for the user. Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a range from about 30 kHz to 300 GHz, such as in a range from about 450 MHz to 6 GHz.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments May perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

1. A bulk acoustic wave resonator including a piezoelectric material layer comprising alternating layers of AlₓSc₁₋ₓN and one of Al_{y}Ga_{1-y}N or Al_{y}In_{1-y}N, 0<x<1, 0<y<1.

2. The bulk acoustic wave resonator of claim 1 further comprising a lower electrode and a seed layer disposed on the lower electrode, the piezoelectric material layer being disposed on the seed layer, the seed layer formed of one of Al_{y}Ga_{1-y}N or Al_{y}In_{1-y}N.

3. The bulk acoustic wave resonator of claim 1 wherein the layers of one of Al_{y}Ga_{1-y}N or Al_{y}In_{1-y}N are thinner than the layers of AlₓSc₁₋ₓN.

4. The bulk acoustic wave resonator of claim 1 wherein the layers of one of Al_{y}Ga_{1-y}N or Al_{y}In_{1-y}N are half as thick or less than the layers of AlₓSc₁₋ₓN.

5. The bulk acoustic wave resonator of claim 1 wherein the layers of one of Al_{y}Ga_{1-y}N or Al_{y}In_{1-y}N are one third as thick or less than the layers of AlₓSc₁₋ₓN.

6. The bulk acoustic wave resonator of claim 1 wherein x=y.

7. The bulk acoustic wave resonator of claim 1 wherein x≠y.

8. The bulk acoustic wave resonator of claim 7 wherein x>y.

9. The bulk acoustic wave resonator of claim 1 wherein the layers of AlₓSc₁₋ₓN have “a” lattice parameters that are lattice matched to the “a” lattice parameters of the layers of one of Al_{y}Ga_{1-y}N or Al_{y}In_{1-y}N.

10. The bulk acoustic wave resonator of claim 1 wherein a layer of pure AlN is applied over at least one of the layers of AlₓSc₁₋ₓN.

11. An acoustic wave filter including the bulk acoustic wave resonator of claim 1.

12. The acoustic wave filter of claim 11, comprising a radio frequency filter.

13. An electronics module including the acoustic wave filter of claim 12.

14. An electronic device including the electronics module of claim 13.

15. A method of forming a bulk acoustic wave resonator, the method comprising:
forming a lower electrode;
depositing a layer of AlₓSc₁₋ₓN above the lower electrode by physical vapor deposition (PVD), 0<x<1;
depositing a layer of one of Al_{y}Ga_{1-y}N or Al_{y}In_{1-y}N on the layer of AlₓSc₁₋ₓN, 0<y<1;
repeating depositing the layers of AlₓSc₁₋ₓN and one of Al_{y}Ga_{1-y}N or Al_{y}In_{1-y}N until the combined thickness of the deposited layers reaches a desired thickness; and
forming an upper electrode on top of the layers of AlₓSc₁₋ₓN and one of Al_{y}Ga_{y-1}N or Al_{y}In_{1-y}N.

16. The method of claim 15 further comprising depositing a seed layer of one of Al_{y}Ga_{1-y}N or Al_{y}In_{1-y}N on an upper surface of the lower electrode prior to depositing a first of the layers of AlₓSc₁₋ₓN on an upper surface of the seed layer.

17. The method of claim 16 further comprising annealing the lower electrode and seed layer prior to depositing the layer of AlₓSc₁₋ₓN above the lower electrode.

18. The method of claim 15 wherein the layers of one of Al_{y}Ga_{1-y}N or Al_{y}In_{1-y}N are deposited by PVD.

19. The method of claim 15 wherein the layers of one of Al_{y}Ga_{y-1}N or Al_{y}In_{1-y}N are deposited by one or atomic layer deposition of Metal-Organic Chemical Vapor Deposition or a similar method.

20. The method of claim 15 further comprising annealing the lower electrode, upper electrode, and the layers of AlₓSc₁₋ₓN and one of Al_{y}Ga_{1-y}N or Al_{y}In_{1-y}N after forming the upper electrode.
